(19) United States
(12) Patent Application Publication
(10) Pub. No.: US 2005/0174100 A1
(43) Pub. Date: Aug. 11, 2005

(54) Detection of electromagnetic pollution

(76) Inventor: Alasdair McLean Philips, Sutton (GB)

Correspondence Address: B. Craig Killough;Barnwell Whaley Patterson & Helms, LLC, P.O. Drawer H, Charleston, SC, 29402, US

(21) Appl. No.: 11/107,213

(22) Filed: Apr. 15, 2005

(30) Foreign Application Priority Data
Apr. 29, 2004 (WO) 2004/036233 A1
Oct. 17, 2003 (WO) PCT/GB03/04509
Oct. 17, 2002 (GB) 0224215.4

(51) Int. Cl. G01R 19/00; G01R 23/00; G01S 5/04

(52) U.S. Cl. 324/76.11; 324/76.19

(57) ABSTRACT

This application relates to the detection of electromagnetic pollution. The invention provides apparatus for monitoring electromagnetic radiation comprising: collection means for sensing electromagnetic radiation within a range of frequencies, means for demodulating the amplitude changes, and means for converting the resultant signals to audible and/or visual indications of the nature and intensity of the radiation sensed by collecting means. The apparatus provided can measure the overall quantity, quality and content of the radiation at any location, with the results presented as visual and/or audible signals. FIG. 1 is a block diagram of apparatus in accordance with the present invention.

This application claims priority on international publication number WO 2004/036233 A1, published Apr. 29, 2004, which claims priority on international application number PCT/GB2003/004509, file Oct. 17, 2003, and which claims priority on GB application serial number 0224215.4, filed Oct. 17, 2002.

### FIELD OF THE INVENTION

This invention relates to the detection of electromagnetic pollution and has particular reference to a device for monitoring amplitude modulated radio-frequency radiation.

### BACKGROUND OF THE INVENTION

It is generally understood that microwave radiation is radiation in the region that extends from 100,000 to 300,000 MHz or 30 cm to one millimetre wavelength. Microwaves were first produced and studied by Hertz in 1886 and today have developed into the principal carriers of high-speed telegraphic data. The effect of Hertzian waves or microwaves in general has usually been regarded as equivalent to the effect produced by heating.

The fact that heat is produced as a result of the bombardment of tissue with high frequency alternating current was discovered towards the end of the 19th century and the possibility of its use for medical purposes was explored as early as 1909. It was soon realized, however, that the generation of too much internal heat could result in normal cells of the body suffering irreversible damage. It has been observed, for example, that the eye lens is particularly prone to damage in this way since excessive exposure to microwave radiation results in the increased chance of cataract formation.

The adverse effect of microwaves on animals in general becomes significant if a considerable temperature rise occurs. As is well known, cells and tissue eventually die at temperatures of the order of 43° C. The effect of microwave radiation heating can be minimized if the heat generated is dissipated within the body by radiation, evaporation and/or conduction. Generally, 1/100 watt (10 milliwatts)/sq.cm can be dissipated in this way without damage, and this level is generally accepted as the maximum permissible thermal dose.

In recent years, however, investigators have documented a variety of long-term non-thermal effects of microwave radiation and have recommended a lower safe limit of 1000 times below that referred to above. The main non-thermal effects appear to be those associated with the nervous system. Exposure has been noted to result in untimely tiring, excitability, and insomnia; it is thought that these effects may be due to changes in the properties of neural membranes or intercellular communications.

Throughout the whole of the 20th century there has been a steady growth in the level of background RF/microwave radiation associated with the increase in communications. Some leading bio-effects scientists have suggested that many of the observed and long-term or effects of radio-frequency signals and microwave radiation are due to the amplitude modulated or pulsed nature of RF signals.

The increasing concern about RF/microwave pollution has prompted a demand for measurement/monitoring of RF pollution particularly in residential areas near to transmitters and a.c. power facilities. This concern has resulted in a need for instruments to measure the quantity, quality and content of this generally injurious radiation. At present, there are many instruments available to measure time-averaged RF radiation; instruments to tune into and analyse specific signals such as a single radio station; or to sweep a frequency spectrum and to display the individual signal levels at the time of the scan. At the present time, however, there is no instrument commercially available to measure the overall quantity, quality and content of the radiation at any location to be monitored and to present the results as a simple visual and/or audible signal.

The increasing concern about RF/microwave pollution has prompted a demand for measurement/monitoring of RF pollution particularly in residential areas near to transmitters and a.c. power facilities. This concern has resulted in a need for instruments to measure the quantity, quality and content of this generally injurious radiation. At present, there are many instruments available to measure time-averaged RF radiation; instruments to tune into and analyse specific signals such as a single radio station; or to sweep a frequency spectrum and to display the individual signal levels at the time of the scan. At the present time, however, there is no instrument commercially available to measure the overall quantity, quality and content of the radiation at any location to be monitored and to present the results as a simple visual and/or audible signal.

### SUMMARY OF THE PRESENT INVENTION

According to one aspect of the present invention, therefore, there is provided apparatus for monitoring electromagnetic radiation which apparatus comprises: —collection means for sensing electromagnetic radiation within a range of frequencies means for demodulating the amplitude changes and means for converting the resultant signals to audible and/or visual indications of the nature and/or intensity of the radiation sensed by the collecting means.

In one aspect of the present invention, there may additionally be provided means for separating out low-frequency information impressed onto the radiation.

In another aspect of the invention, the collection means may be an antenna and may include a filter circuit to limit responses in selected frequency ranges. In a further aspect of the invention, said filter circuit may be a passive circuit. In an alternative embodiment, the filter circuit may be an active circuit and may further include means for up to a 20 dB mid-band RF gain. In yet a further aspect of the present invention, the demodulation means may be a pair of zero-bias Schottky microwave diodes.

The conversion means may be an audio pre-amplifier and may further include frequency response means, which may preferably be present.

The monitoring apparatus in accordance with one embodiment of the present invention provides an audible output signal. In locations that have significant RF pollution, the user hears a combination of signals and can assess both the amplitude, the quantity and quality of the sound signal and hence the amplitude and quality of the polluting radiation. The signal may be judged on the basis of its softness, harshness, and any pulsing, buzzing or screeching noises, which form the texture of the overall audible signal. The nature of the signal affords the user evidence of the nature of the RF signal and in particular gives an indication of the level of modulation of the signal. The volume will be indicative of the quantum or amount of the pollution. In one further aspect of the invention, the apparatus may be provided with a loudspeaker and an output signal socket to enable the signal to be recorded for future reference and analysis.

Following is a description by way of example only and with reference to the accompanying informal drawings of methods of carrying the invention into effect.

### DESCRIPTION OF THE DRAWINGS

FIG. 1 is a block diagram of apparatus in accordance with the present invention.

FIG. 2 is a detailed diagram of the antenna filter and optional RF amplifier of block A of FIG. 1.

FIG. 3 is a detailed diagram of the detector circuitry of block B of FIG. 1.

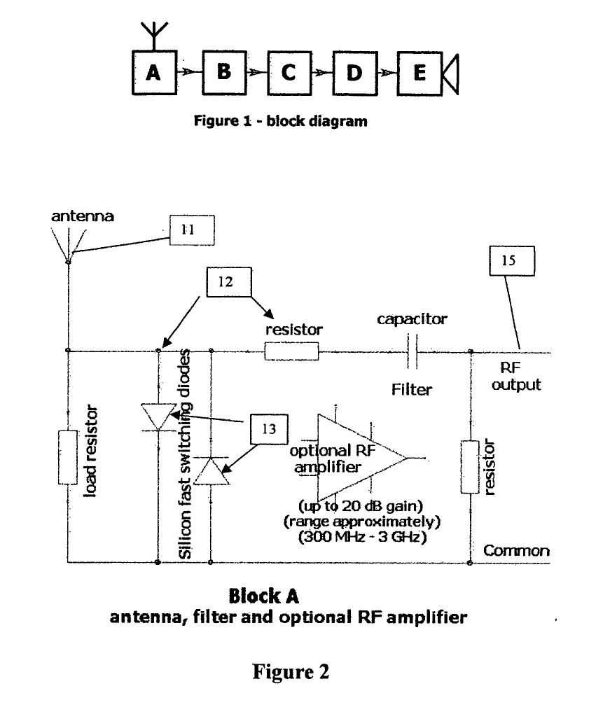

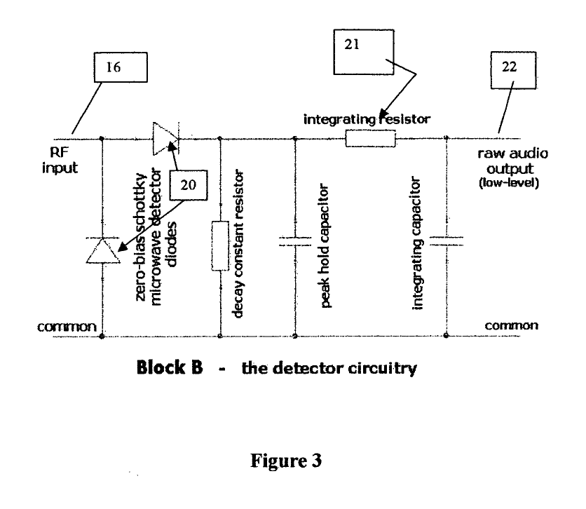

### DETAILED DESCRIPTION OF THE PREFERRED EMBODIMENT

The antenna 11 senses radio frequency radiation and passes it to a simple passive RC filter circuit indicated generally at 12 incorporating a pair of silicon fast switching diodes 13. The parameters of each of the components of this circuit is selected to limit responses to signals in frequency ranges, which are deemed not to be injurious, e.g. long to short wavebands and FM radio. In an alternative embodiment of the invention, this passive circuit may be changed to an active filter, which serves to provide a 20 dB gain in respect of signals received within the range of 300 MHz to 3 GHz. The fast acting silicon switching diodes 13 serve to protect the instrument against overload.

The RF signal output 15 from block A is supplied to input 16 of block B and acts to demodulate any amplitude modulation on the signal using zero-bias Schottky microwave diodes 20. The demodulated signal is then subjected to further filtering by capacitors and resistors indicated generally at 21.

The output from block B at 22 is a raw audio output, which is then supplied to an audio pre-amplifier stage with an adjustable but preset frequency response. The audio pre-amplifier may be an audio pre-amplifier of generally known design but the frequency response setting should be set to produce the most effective noise for the user to judge the pulsing RF/microwave pollution at the test location.

The output from the audio pre-amplifier is then supplied to a standard audio amplifier with a volume control of a type well known and used in radio receivers and hi-fi equipment. The output from the audio amplifier is passed to a loudspeaker or headphones that converts the electrical signals into sound. An output socket or jack may be provided for feeding the signal to another device such as a portable tape recorder for recording the signal for subsequent review and analysis.

The equipment is housed in a small box and powered by a replaceable standard or a rechargeable battery. The user takes the box constituting the apparatus in accordance with the present invention to a test location and on activation, the antenna senses the ambient radiation, an audible signal is then emitted which gives an indication of the nature and intensity of the radiation present at the test location. In an area not polluted by any significant level of RF radiation, the monitor will be substantially silent or, at the most, with the volume control at a maximum position, will make a quiet hissing sound.

In locations of significant RF/microwave pollution, the user will hear a combination of signals and can assess both the amplitude and quality of the signals and thereby gain some guidance as to the overall texture of the polluting radiation.

1. Apparatus for monitoring non-thermal microwave electromagnetic radiation comprising:
collection means for sensing electromagnetic radiation over a range of frequencies within the microwave spectrum, which radiation has an amplitude modulated or pulsed nature, means for demodulating the amplitude changes, and means for converting the resultant signals to audible and/or visual indications of the overall nature and/or intensity of the radiation over the range of frequencies sensed by the collecting means.

2. Apparatus for monitoring electromagnetic radiation according to claim 1, further comprising means for separating out low frequency information impressed onto the radiation.

3. Apparatus for monitoring electromagnetic radiation according to claim 1 wherein the collection means comprises at least one antenna.

4. Apparatus for monitoring electromagnetic radiation according to claim 1, wherein the collection means include a filter circuit to limit responses in selected frequency ranges.

5. Apparatus for monitoring electromagnetic radiation according to claim 1 wherein the demodulation means comprises a pair of zero bias shottky microwave diodes.

6. Apparatus for monitoring electromagnetic radiation according to claim 1 wherein the conversion means comprises an audio preamplifier.

7. Apparatus for monitoring electromagnetic radiation as claimed in claim 1 wherein the apparatus is provided with a signal output means to enable the signal to be recorded for future reference and analysis.

8. Apparatus for monitoring electromagnetic radiation as claimed in claim 1 wherein the means for converting the signals is adapted to provide an audible output indicating the nature and/or intensity of the radiation.

9. Apparatus for monitoring electromagnetic radiation according to claim 2 wherein the collection means comprises at least one antenna.
